(19) United States
(12) Patent Application Publication
(10) Pub. No.: US 2021/0193715 A1
(43) Pub. Date: Jun. 24, 2021

(54) FINFET PIXEL ARCHITECTURE FOR IMAGE SENSOR PACKAGES AND RELATED METHODS

(71) Applicant: SEMICONDUCTOR COMPONENTS INDUSTRIES, LLC, Phoenix, AZ (US)

(72) Inventor: John P. McCARTEN, Penfield, NY (US)

(73) Assignee: SEMICONDUCTOR COMPONENTS INDUSTRIES, LLC, Phoenix, AZ (US)

(21) Appl. No.: 16/720,287

(22) Filed: Dec. 19, 2019

(51) Int. Cl. H01L 27/146; H01L 29/49; H01L 21/027; H01L 29/66; H01L 21/265; H01L 21/762; H01L 29/78; H01L 21/306

(52) U.S. Cl. CPC H01L 27/14616; H01L 21/30604; H01L 27/1463; H01L 27/14629; H01L 29/4916; H01L 27/14621; H01L 27/14627; H01L 27/14689; H01L 21/0273; H01L 29/66795; H01L 21/26513; H01L 21/762; H01L 27/14636; H01L 27/14685; H01L 29/7851; H01L 27/14645

(57) ABSTRACT

A FinFET pixel architecture for an image sensor is disclosed. Specific implementations of a pixel of an image sensor may include a photodiode region coupled with a transfer region coupled with one or more fin field-effect transistors (FinFETs). The one or more FinFETs may be one of a transfer transistor, a storage gate, a reset transistor, a source follower transistor, a row select transistor, or an anti-blooming gate.

### BACKGROUND

### 1. Technical Field

Aspects of this document relate generally to semiconductor devices, such as image sensors.

### 2. Background

Image sensors are used in a variety of electronic devices that have a camera, such as vehicles, smart phones, tablets, and other devices having a camera. Light striking a pixel of an image sensor is converted into an electric signal. The electric signal may be processed using a digital signal processor and may be used to form an image.

### SUMMARY

Implementations of a pixel of an image sensor may include: a photodiode region coupled with a transfer region coupled with one or more fin field-effect transistors (FinFETs). The one or more FinFETs may be one of a transfer transistor, a storage gate, a reset transistor, a source follower transistor, a row select transistor, or an anti-blooming gate.

Implementations of a pixel of an image sensor may include one, all, or any of the following:

The one or more FinFETs may be aligned with a deep trench isolation region adjacent to the photodiode region.

The photodiode region may be defined by the deep trench isolation region and the deep trench isolation region may include metal.

The one or more FinFETs may be arranged around one of the photodiode region or a metal reflector.

The pixel of the image sensor may include two or more FinFETs. At least one of the two or more FinFETs may have a different size.

The one or more FinFETs may be formed around a perimeter of the pixel.

Each FinFET of the one or more FinFETs may include silicon and a wrapped polysilicon gate.

The pixel of the image sensor may include a color filter array coupled over the photodiode region.

The pixel of the image sensor may include a microlens coupled over the color filter array.

Implementations of a pixel array may include: at least two pixels. Each of the two pixels may include a photodiode region. The photodiode region may be surrounded by one or more field-effect transistors (FinFETs). The one or more FinFETs may be one of a transfer transistor, a storage gate, a reset transistor, a source follower transistor, a row select transistor, or an anti-blooming gate.

Implementations of a pixel array may include one, all, or any of the following:

The pixel array may include two or more FinFETs. The two or more FinFETs may be arranged around the at least two pixels.

The pixel array may include two or more FinFETs. At least one of the two or more FinFETs may have a different size.

The one or more FinFETs may be formed around a perimeter of each pixel of the at least two pixels.

Implementations of a method of forming a pixel may include: providing a silicon substrate, patterning a first photoresist layer on the silicon substrate, and etching to form one or more field-effect transistor (FinFET) structures on the silicon substrate. The method may further include depositing a second photoresist layer onto the one or more FinFET structures, implanting a photodiode region, and removing the second photoresist layer from the one or more FinFET structures. The method may further include patterning a third photoresist layer over the photodiode region, implanting the one or more FinFET structures, and implanting the photodiode region in a chained pattern.

Implementations of a method of forming a pixel may include one, all, or any of the following:

The method may include implanting a pinning implant over a storage gate FinFET structure of the one or more FinFET structures.

The method may include implanting an isolation region.

The method may include growing oxide on the silicon substrate.

The method may include depositing a gate on the one or more FinFET structures and etching the gate.

The method may include performing backside deep trench isolation etching.

The method may include forming and depositing a dielectric layer, forming one or more vias, and forming one or more traces coupled to the one or more vias. The method may further include forming a passivation layer and depositing an anti-reflective coating. The method may further include forming a color filter array and forming a plurality of microlenses over the color filter array.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 illustrates a silicon substrate with a photoresist layer deposited and etched to form one or more field-effect transistor (FinFET) structures;

FIG. 2 illustrates a silicon substrate with a photodiode region implanted;

FIG. 3 illustrates a silicon substrate with a photodiode region implanted in a chained pattern;

FIG. 4 illustrates a silicon substrate with a storage gate FinFET structure implanted;

FIG. 5 illustrates a silicon substrate with a pinning implant implanted over the storage gate FinFET structure;

FIG. 6 illustrates a three-dimensional view of a pixel of an image sensor;

FIG. 7 illustrates a top view of a pixel array of an image sensor;

FIG. 8 illustrates a cross-sectional side view of the pixel array of FIG. 7; and

FIG. 9 illustrates a circuit diagram of a pixel of an image sensor; and

FIG. 10 illustrates a 1x2 circuit diagram of a pixel of an image sensor.

### DESCRIPTION

This disclosure, its aspects and implementations, are not limited to the specific components, assembly procedures or method elements disclosed herein. Many additional components, assembly procedures and/or method elements known in the art consistent with the intended FinFET pixel architecture will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such FinFET pixel architecture, and implementing components and methods, consistent with the intended operation and methods.

The use of a field-effect transistor (FinFET) pixel architecture within an image sensor may create a structure that may improve charge capacity, global shutter efficiency, quantum efficiency, angle response, noise, and frame rate performance. The charge capacity may be improved by increasing the storage gate area using a FinFET region, which may also allow for a larger photodiode region of the pixel. The global shutter efficiency may be improved by hiding the storage gate node beneath a backside deep trench isolation. Further, a wider source follower transistor may reduce read noise and increase frame rate as the transconductance increases.

In this disclosure, the FinFET pixel architecture can not only be used for the pixel transistors, but also for the storage gate region of the image sensor. The use of the FinFET architecture in this way reduces the footprint of the storage gate, which may improve global shutter efficiency, as the storage gate node may be hidden under the backside deep trench isolation. The FinFET structure may increase the storage gate area, which may increase the storage gate capacity. The photodiode capacity may also increase due to the smaller storage gate footprint. In various implementations, a silicon substrate with a thickness greater than 3 μm may be used with a PMOS pixel structure, using p-type silicon, or an NMOS pixel structure, using n-type silicon.

Disclosed herein are implementations of pixels, portions thereof, and circuits thereof. The pixels disclosed herein may be global shutter pixels, overflow based high dynamic range (HDR) pixels, or any other type of pixel. While many of the implementations refer to a single active pixel, it is understood that the pixel may be one of a number of pixels in an array of pixels arranged in multiple rows and multiple columns, each column shared by multiple pixel outputs from the multiple rows of pixels to enable a pipelined or sequential readout of each row of pixels in the array through the shared columns coupled thereto. The array of pixels may be formed in a layer of semiconductor material on a common, shared substrate, which may include other elements and circuits of the image sensor. The semiconductor layer may include, by non-limiting example, silicon, silicon carbide, germanium, indium-gallium-arsenide, any combination thereof, or any other semiconductor material.

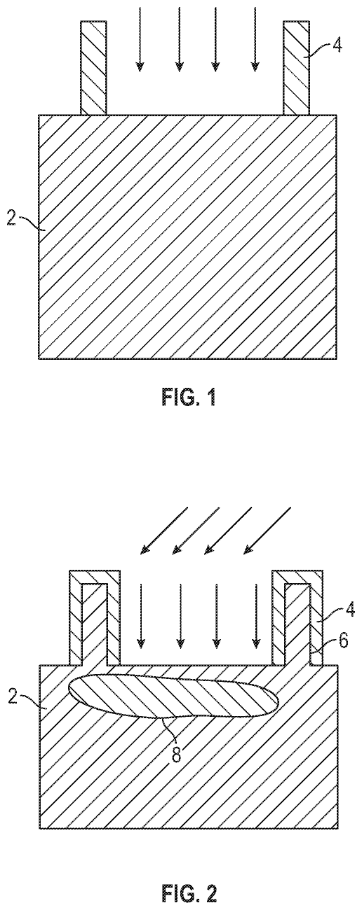

Referring to FIG. 1, a silicon substrate with a photoresist layer deposited and etched to form one or more field-effect transistor (FinFET) structures is illustrated. In an implementation of a method of forming a pixel, a silicon substrate 2 is provided. As described herein, the pixel is part of an image sensor, which, in various implementations, may be a front side illumination (FSI) image sensor, or a backside illumination (BSI) image sensor. As illustrated, a photoresist layer 4 is patterned onto the silicon substrate 2, and an etching process is illustrated taking place in the direction of the arrows as shown.

Referring to FIG. 2, a silicon substrate with a photodiode region following etching during an implantation operation is illustrated. In the implementation of the method of forming a pixel, the silicon substrate 2 is etched to form one or more field-effect transistor (FinFET) structures 6 on the silicon substrate 2. As illustrated, a photoresist layer 4 was then deposited onto the one or more FinFET structures 6 in order to protect the one or more FinFET structures from being implanted. In the implementation illustrated in FIG. 2, a photodiode region 8 is being implanted into the silicon substrate 2. As illustrated, the photodiode implantation process may proceed in multiple steps, a first implant performed substantially perpendicularly with the largest planar surface of the substrate 2 shown by the arrows parallel with the FinFET structures 6. A second angled implant is then performed in a direction represented by the angled arrows above the FinFET structures 6. The effect of combining the first and second implant steps is forming a photodiode region 8 that extends below one of the FinFET structures but not below the other FinFET structure. In various implementations, the photodiode region includes a region where the dopant prepares the substrate material to generate holes in response to receiving electromagnetic radiation which may be light in various implementations. In various implementations, the photodiode region may also include one or more silicon based transistors.

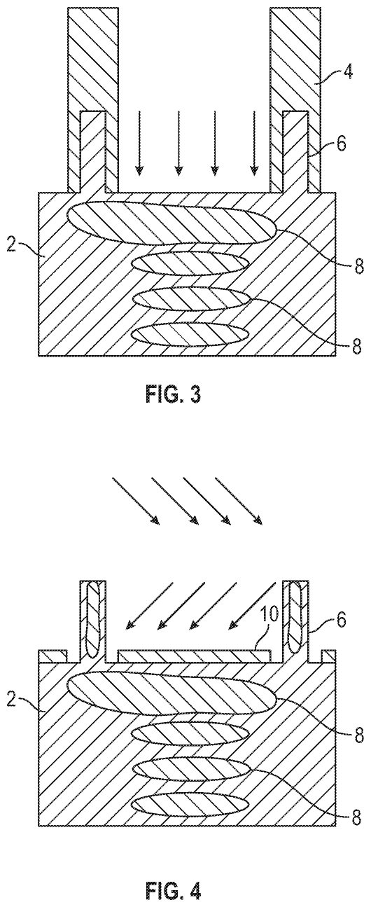

Referring to FIG. 3, a silicon substrate with a photodiode region 8 implanted in a chained pattern is illustrated following multiple additional implant steps at varying energies to create doped regions at different depths into the silicon substrate 2. Throughout the various implantation steps, the photoresist layer 4 surrounds the FinFET 6 structures to prevent the FinFET structures from being implanted with the dopant being used to implant the photodiode region 8.

Referring to FIG. 4, a silicon substrate with a FinFET structure implanted is illustrated. In the implementation illustrated in FIG. 4, the FinFET structures will be involved in functioning as a storage gate. As illustrated, in the implementation of a method of forming a pixel, the photoresist layer illustrated in FIG. 3 is removed from the one or more FinFET structures 6. Another photoresist layer 10 is then patterned over the photodiode region 8 and the silicon substrate 2, as illustrated. In such implementations, the FinFET structures 6 are then implanted while the photoresist layer 10 protects the photodiode region 8 from implantation with the dopant used to implant the one or more FinFET structures 6. As illustrated, to carry out the implantation of both sides of each of the one or more FinFET structures, two successive angled implants may be carried out as indicated by the angled lines in FIG. 4.

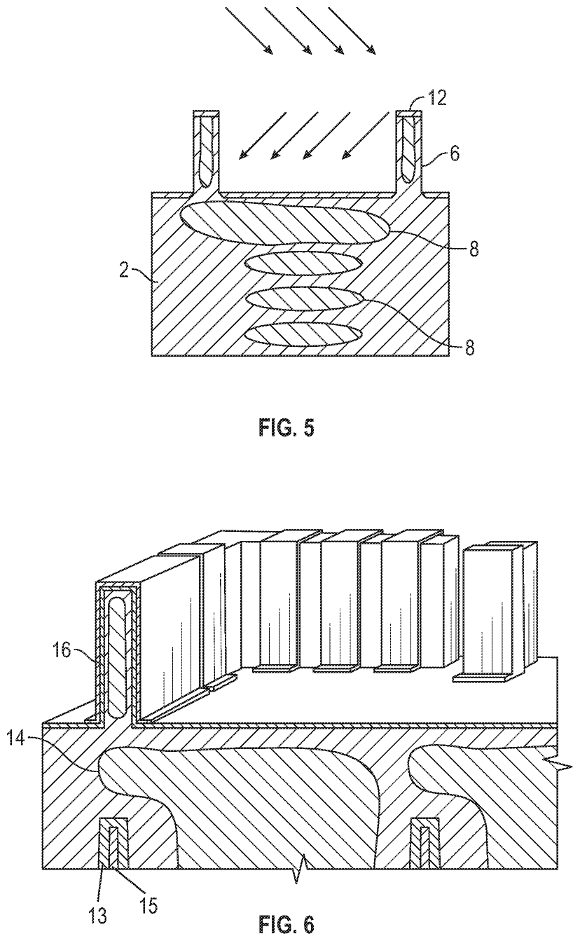

Referring to FIG. 5, a silicon substrate with a pinning implant implanted over the storage gate FinFET structure is illustrated. In various implementations, a pinning implant 12 may be implanted over a storage gate FinFET structure 6, using two successive angled implants indicated by the angled lines in FIG. 5. In such implementations, the pinning implant may be disposed at the top of each of the one or more FinFET structures 6 and in the top surface of the photodiode region 8. In various implementations, an isolation region may then be implanted. The implant is carried out after the photoresist layer 10 of illustrated in FIG. 4 has been removed. In other various implementations, oxide may be grown on the silicon substrate and/or the one or more FinFET structures.

Following the formation of the one or more FinFET structures and the photodiode region, the remaining transistor structures and related interconnect structures between the various transistor structures to form the pixel circuit structures is then carried out. Depending on the particular function of the transistor or device in which the one or more FinFET structures will be included, additional processing may be carried out. For example, in a particular implementations, a gate may be deposited on the FinFET structures and the gate may be patterned using photolithography operations and then etched. In other implementations backside deep trench isolation etching may then be performed on the silicon substrate to help electrically isolate the photodiode regions of each device from each other device. In the process of forming one or more layers of interconnect between the various devices in the pixel a dielectric layer may be formed and deposited over the one or more FinFET structures and the photodiode regions. One or more vias are then formed into the dielectric layer to contact the desired portions of the devices (gate, etc.). One or more traces/metal lines are then formed into the dielectric layer in contact with the one or more vias forming routing between the portions of the devices. The process of depositing dielectric layers, forming vias, and then forming traces may be repeated as many times as needed to form all the electrical routing needed to create the desired pixel circuit. In various implementations, the vias may include a electrically conductive material, such as tungsten. After one or more layers of interconnect have been formed, one or more passivation layers are then formed over the final layer of the one or more layers of interconnect. In various implementations, an anti-reflective coating may be formed over the one or more passivation layers. In particular implementations of image sensors, a color filter array may be formed over the one or more passivation layers. In various implementations, a plurality of microlenses may then be formed over the color filter array.

Referring to FIG. 6, a three-dimensional perspective view of a pixel of an image sensor is illustrated. The pixel includes a photodiode region 14 and FinFET structures 16 that form various devices, as illustrated. The FinFETs 16 are formed around a perimeter of the pixel, as illustrated. In various implementations, the FinFETs 16 are aligned with a deep trench isolation region adjacent to the photodiode region 14. In such implementations, the photodiode region 14 is defined by the deep trench isolation region 13 and the deep trench isolation region 13 includes metal 15 therein.

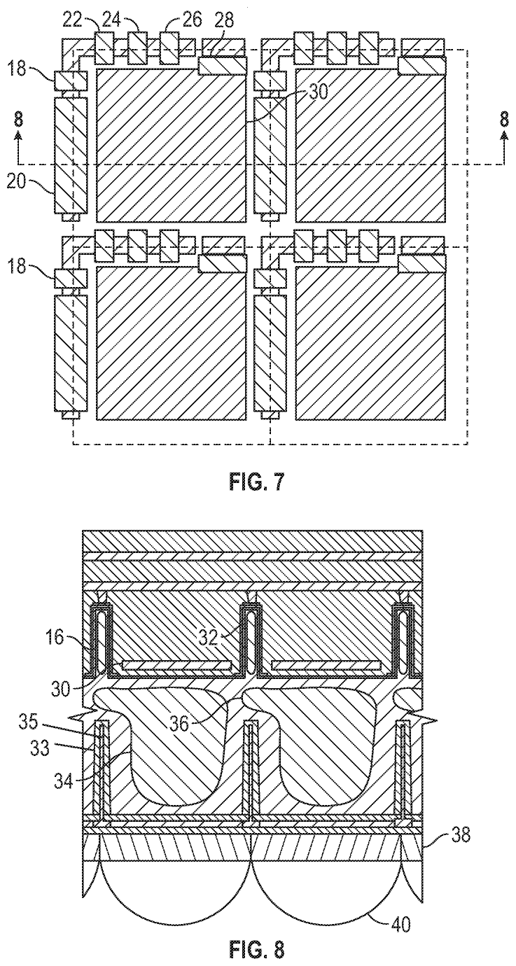

Referring to FIG. 7, a top view of the pixel array of an image sensor of FIG. 6 is illustrated showing four pixels joined together. In various implementations, the pixel array is a capacitor-less design. As illustrated, each pixel of the pixel array is surrounded by FinFET structures 16. As illustrated, the FinFET structures 16 are a transfer transistor 18, a storage gate 20, a reset transistor 22, a source follower transistor 24, a row select transistor 26, and an anti-blooming gate 28. As illustrated, the FinFET structures 16 are of different sizes. In various implementations, the FinFET structures are disposed around a photodiode region which may include a metal reflector 30. In various implementations, the FinFETs 16 are aligned with a deep trench isolation region adjacent to the photodiode region. In such implementations, the photodiode region is defined by the deep trench isolation region. In other various implementations, the FinFETs 16 are arranged around just the photodiode region which does not include a metal reflector.

Referring to FIG. 8, a cross-sectional side view of the pixel array of FIG. 7 is illustrated showing the interconnect structure above the FinFET structures 16. Each pixel in the pixel array includes a storage gate 32, a photodiode region 34, and a transfer region 36, as illustrated. The transfer region 36 is coupled to FinFET structures 16, which may include a storage gate, a reset transistor, a source follower transistor, a row select transistor, or an anti-blooming gate, though a storage gate 32 is depicted in this illustration. In various implementations, each FinFET may include silicon and a wrapped polysilicon gate. In various implementations, the FinFETs 16 are aligned with a deep trench isolation region adjacent to the photodiode region 34. In such implementations, the photodiode region 34 is defined by the deep trench isolation region 33 and the deep trench isolation region 33 includes metal 35. In various implementations, each pixel may include a metal reflector 30. As illustrated, a color filter array 38 is coupled over the photodiode region 34 and a microlens 40 is coupled over the color filter array 38.

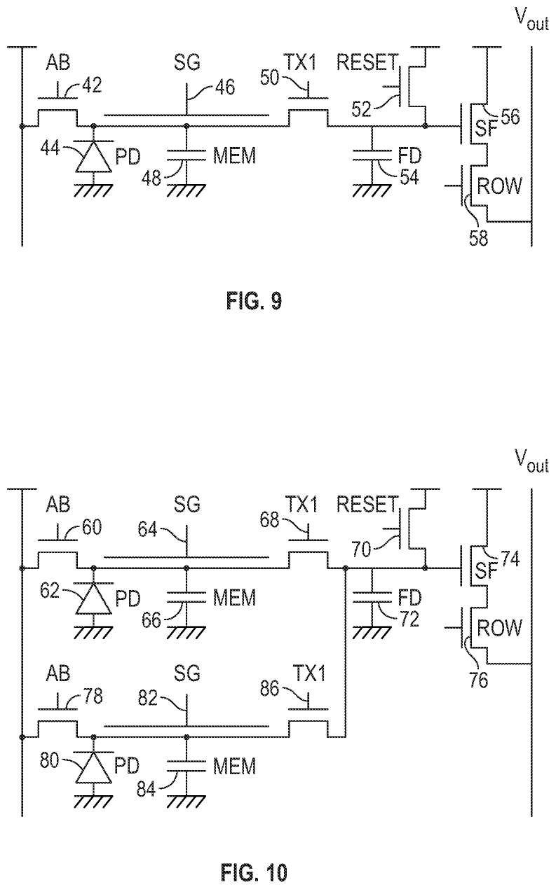

Referring to FIG. 9, a circuit diagram of a pixel circuit implementation for an image sensor is illustrated. The FinFETs disclosed herein can be used to form one or more of the various circuit components disclosed in the circuit diagram. As illustrated, the pixel circuit includes various gates and transistors. Where all of these are implemented as FinFETs, these various circuit components become positioned around/arranged around the photodiode region of the pixel of the image sensor. As illustrated, an anti-blooming gate 42, a photodiode 44, a storage gate 46, a memory capacitor 48, a transfer transistor 50, a reset transistor 52, a floating diffusion 54, a source follower transistor 56, and a row select transistor 58 all are included in this pixel circuit implementation and are operatively electrically coupled together. As illustrated, the row select transistor 58 may also be coupled with a voltage output. In various implementations, one, some, or all of these transistor, gate, or other circuit components could be implemented using a FinFET structure like any disclosed in this document.

Referring to FIG. 10, a 1x2 circuit diagram of an implementation of a pixel circuit for an image sensor is illustrated. As previously discussed any of the FinFET implementations disclosed in this document could be employed to form various of the circuit components in this diagram. As illustrated, an anti-blooming gate 60, a photodiode 62, a storage gate 64, a memory capacitor 66, a transfer transistor 68, a reset transistor 70, a floating diffusion 72, a source follower transistor 74, and a row select transistor 76 are all coupled together. As illustrated, a second anti-blooming gate 78, a second photodiode 80, a second storage gate 82, a second memory capacitor 84, and a second transfer transistor 86 are coupled in series with the aforementioned circuit components to form the second pixel circuit of the 1x2. A wide variety of different pixel circuit types may implement FinFET device implementations like those disclosed herein using the principles disclosed in this document.

In places where the description above refers to particular implementations of a FinFET pixel architecture and implementing components, sub-components, methods and sub-methods, it should be readily apparent that a number of modifications may be made without departing from the spirit thereof and that these implementations, implementing components, sub-components, methods and sub-methods may be applied to other FinFET pixel architectures.

What is claimed is:

1. A pixel of an image sensor, comprising:
a photodiode region coupled with a transfer region coupled with one or more fin field-effect transistors (FinFETs);
wherein the one or more FinFETs are one of a transfer transistor, a storage gate, a reset transistor, a source follower transistor, a row select transistor, or an anti-blooming gate.

2. The pixel of claim 1, wherein the one or more FinFETs are aligned with a deep trench isolation region adjacent to the photodiode region.

3. The pixel of claim 2, wherein the photodiode region is defined by the deep trench isolation region and the deep trench isolation region comprises metal.

4. The pixel of claim 1, wherein the one or more FinFETs are arranged around one of the photodiode region or a metal reflector.

5. The pixel of claim 1, further comprising two or more FinFETs, at least one of the two or more FinFETs having a different size.

6. The pixel of claim 1, wherein the one or more FinFETs are formed around a perimeter of the pixel.

7. The pixel of claim 1, wherein each FinFET of the one or more FinFETs comprises silicon and a wrapped polysilicon gate.

8. The pixel of claim 1, further comprising a color filter array coupled over the photodiode region.

9. The pixel of claim 8, further comprising a microlens coupled over the color filter array.

10. A pixel array, comprising:
at least two pixels, each of the two pixels comprising a photodiode region, the photodiode region surrounded by one or more field-effect transistors (FinFETs);
wherein the one or more FinFETs are one of a transfer transistor, a storage gate, a reset transistor, a source follower transistor, a row select transistor, or an anti-blooming gate.

11. The pixel array of claim 10, further comprising two or more FinFETs, wherein the two or more FinFETs are arranged around the at least two pixels.

12. The pixel array of claim 10, further comprising two or more FinFETs, at least one of the two or more FinFETs having a different size.

13. The pixel array of claim 10, wherein the one or more FinFETs are formed around a perimeter of each pixel of the at least two pixels.

14. A method of forming a pixel, comprising:
providing a silicon substrate;
patterning a first photoresist layer on the silicon substrate;
etching to form one or more field-effect transistor (FinFET) structures on the silicon substrate;
depositing a second photoresist layer onto the one or more FinFET structures;
implanting a photodiode region;
removing the second photoresist layer from the one or more FinFET structures;
patterning a third photoresist layer over the photodiode region;
implanting the one or more FinFET structures; and
implanting the photodiode region in a chained pattern.

15. The method of claim 14, further comprising implanting a pinning implant over a storage gate FinFET structure of the one or more FinFET structures.

16. The method of claim 14, further comprising implanting an isolation region.

17. The method of claim 14, further comprising growing oxide on the silicon substrate.

18. The method of claim 14, further comprising depositing a gate on the one or more FinFET structures and etching the gate.

19. The method of claim 14, further comprising performing backside deep trench isolation etching.

20. The method of claim 14, further comprising:
forming and depositing a dielectric layer;
forming one or more vias;
forming one or more traces coupled to the one or more vias;
forming a passivation layer;
depositing an anti-reflective coating;
forming a color filter array; and
forming a plurality of microlenses over the color filter array.
